(19) United States
(12) Patent Application Publication
(10) Pub. No.: US 2025/0273687 A1
(43) Pub. Date: Aug. 28, 2025

(54) High-Performance Lithium-Sulfur Batteries Enabled by Superior Lithium Anodes and Sulfur Cathodes

(71) Applicant: BOARD OF TRUSTEES OF THE UNIVERSITY OF ARKANSAS, Little Rock, AR (US)

(72) Inventors: Xiangbo Meng, Little Rock, AR (US); Aiying Shao, Little Rock, AR (US)

(73) Assignee: BOARD OF TRUSTEES OF THE UNIVERSITY OF ARKANSAS, Little Rock, AR (US)

(21) Appl. No.: 18/858,291

(22) PCT Filed: Apr. 24, 2023
(86) PCT No.: PCT/US2023/019680

§ 371 Date: Oct. 18, 2024

Related U.S. Application Data
(60) Provisional application No. 63/333,922, filed on Apr. 22, 2022.

(51) Int. Cl. H01M 4/62

(52) U.S. Cl. CPC H01M 4/628; H01M 4/0428; H01M 4/131; H01M 4/1391; H01M 4/366; H01M 4/48; H01M 4/623; H01M 4/625; H01M 10/0525

(57) ABSTRACT

A coating via molecular layer deposition (MLD) to protect Li anodes and a coating via atomic layer deposition (ALD) to modify S cathodes.

### RELATED APPLICATIONS

This application is a 371 National Phase of PCT/US2023/019680 filed on Apr. 24, 2023, which claims priority to U.S. Provisional Application No. 63/333,922, filed on Apr. 22, 2022, both of which are incorporated herein in their entirety.

### BACKGROUND OF THE INVENTION

Currently, transportation is consuming ˜30% of the total energy in the United States, while petroleum supplies over 90% of the energy needs of transportation. To deal with the ever-aggravating depletion of fossil fuels and environmental issues, transportation electrification represents a renewable clean solution. To date, however, the market share of battery-powered electric vehicles (BEVs) is still very low, less than 3%. To boost the market share of BEVs, BEVs need a battery system enabling a high energy density of ≥300 Wh/kg and an affordable cost of ≤$125/kWh. However, the currently state-of-the-art lithium-ion batteries (LIBs) are unsatisfactory in energy density and cost.

In this context, Li-S batteries have stood out, for they have a high theoretical energy density of 2500 Wh/kg (5-10 times higher than that of LIBs) and a low cost of ˜$70/kWh (the lowest one so far). The advantages of Li-S batteries mainly lie in the following aspects. First, S enables the highest theoretical capacity of 1675 mAh/g among all the solid elements as cathodes. Second, S is among the most abundant elements on earth. There is a several-million-ton surplus of S production worldwide. Li-S batteries have a potentially lower cost of ˜$70/kWh, compared to the $300/kWh of state-of-the-art LIBs.

Third of all the anode candidates at room temperature, Li metal also has the highest theoretical capacity of 3860 mAh/g. Fourth, Li metal has the lowest negative electrochemical potential (−3.04 V versus the standard hydrogen electrode). Fifth, a Li-S cell has an average cell voltage of 2.15 V (versus Li/Li+), which improves battery safety. As a result, Li-S batteries theoretically enable an energy density of 2500 Wh/kg, 5-10 times higher than those of LIBs. Thus, Li-S batteries exhibit tremendous advantages over LIBs, including higher energy density, lower cost, and better battery safety. These jointly make Li-S batteries one of the ideal candidates for transportation electrification. While promising, Li-S batteries still experience some serious issues related to both S cathodes and Li metal anodes, which inhibit their commercialization.

Also, Li-S batteries are facing issues associated with their Li metal anodes and S cathodes. There have three main issues on the S cathode side: (1) Low conductivity of sulfur(S) and lithium sulfide (Li₂S); (2) Dissolution of intermediate lithium polysulfides (LPSs, Li₂Sₙ) into the ether electrolyte; and (3) Large volumetric changes of the sulfur cathode. The issues of Li anodes lie in two main aspects: (1) non-uniform and unstable solid electrolyte interphase (SEI) and (2) Li dendritic growth. Li metal is highly reactive to organic liquid electrolytes (OLEs), leading to the formation of an SEI layer on its surface.

### BRIEF SUMMARY OF THE INVENTION

In one embodiment, the present invention provides a coating via molecular layer deposition (MLD) to protect Li anodes and a coating via atomic layer deposition (ALD) to modify S cathodes.

In another embodiment, the present invention configures the lithium (Li) anodes and sulfur(S) cathodes to achieve high-energy Li-S batteries with high performance, in terms of their sustainable capacity, Coulombic efficiency, and cyclability. The embodiments of the present invention address the issues with both Li anodes and S cathodes to accomplish much higher energy density of Li-S batteries and much longer lifetime. The ALD and MLD methods are facile, cost-effective, and accurate.

In another embodiment, the present invention provides a Li-S battery using ALD-TiO₂ coatings to adsorb LPSs to inhibit the shuttle of LPSs.

In another embodiment, the present invention provides a Li-S battery using an MLD-LiGL coating (GL=glycerol) to mitigate side reactions between shuttled LPSs and Li metal anode. In addition, the MLD-LiGL coating hinders dendritic growth and SEI formation on the Li metal anode.

In another embodiment, the present invention provides a high-performance lithium-sulfur batteries enabled by superior lithium anodes and sulfur cathodes having the following advantages:
1. Facile to practice;
2. Much higher energy density;
3. much higher loading of S in cathodes; and
4. Very effective in protecting Li anodes.

### BRIEF DESCRIPTION OF THE SEVERAL VIEWS OF THE DRAWINGS

In the drawings, which are not necessarily drawn to scale, like numerals may describe substantially similar components throughout the several views. Like numerals having different letter suffixes may represent different instances of substantially similar components. The drawings illustrate generally, by way of example, but not by way of limitation, a detailed description of certain embodiments discussed in the present document.

(b) During a charge process, both lithium ions (Li+) and electrons (e⁻) move to the Li anode. (c) During a discharge, S evolves into different intermediate polysulfides (Li₂S₈, Li₂S₆, Li₂S₄, and Li₂S₂) before reduced into Li₂S; vice versa.

FIG. 1A illustrates the structure and electrochemical mechanism of Li-S batteries during a discharge process, both Li⁺ and e⁻ move to the S cathode.

FIG. 1B illustrates the structure and electrochemical mechanism of Li-S batteries during a charge process, both Li⁺ and e⁻ move to the Li anode.

FIG. 1C illustrates the structure and electrochemical mechanism of Li-S batteries during a discharge, S evolves into different intermediate polysulfides (Li₂S₈, Li₂S₆, Li₂S₄, and Li₂S₂) before reduced into Li₂S; vice versa.

FIG. 2 shows how dissolved long-chain lithium polysulfides (Li₂Sₙ, 3≤n≤8) diffuse to the Li anode with the production of lower-order polysulfides by reduction and the low-order polysulfides diffuse back to the S cathode to be re-oxidized.

FIG. 3A shows an SEI layer formed on Li.

FIG. 3B shows cracks formed on the SEI layer during plating.

FIG. 3C shows dendrites formed with continuous plating.

FIG. 3D shows isolated Li formed during stripping.

FIG. 3E shows porous Li anode formed after multiple cycles, featuring thickened SEI and dead Li.

FIG. 4A is an scanning electron microscopy (SEM) image of the S_{CB} cathode electrode before discharge-charge cycling. FIG. 4B is an SEM image of the S_{N-GNS} cathode electrode before discharge-charge cycling.

FIG. 4C is an SEM image of the SC_{B/N-GNS} cathode electrode before discharge-charge cycling.

FIG. 4D is an SEM image of the S_{CB} cathode electrode after 60 discharge-charge cycles.

FIG. 4E is an SEM image of the S_{N-GNS} cathode electrode after 60 discharge-charge cycles.

FIG. 4F is an SEM image of the S_{CB/N-GNS} cathode electrode after 60 discharge-charge cycles.

FIGS. 5A, 5B and 5C are SEM images of the S_{CB} cathode and its corresponding EDX mapping image of (b) carbon and (c) sulfur.

FIGS. 5D-5E are SEM images of the S_{N-GNS} electrode and its corresponding EDX mapping image of (e) carbon and (f) sulfur.

FIG. 6 shows the XRD patterns of the pristine S powder, and electrode sheets of

different conductive additives.

FIG. 7A shows the electrochemical performance, namely the cyclability and sustainable capacity, of the S cathode electrodes, with different conductive additives.

FIG. 7B shows the electrochemical performance, namely the capacity retention, of the S cathode electrodes, with different conductive additives.

FIG. 7C shows the electrochemical performance, namely the coulombic efficiency at a constant current density of 100 mA/g, with different conductive additives.

FIG. 7D shows the electrochemical performance, namely the rate capability of the S cathodes, in which the S cathodes were tested for 10 cycles at each current density of 0.1, 0.2, 0.5, 1, and 2 C, of the S cathode electrodes, with different conductive additives.

FIG. 8A shows the electrochemical performance of the S cathode electrodes with different amounts of TiO₂ nanoparticles at a current density of 600 mA/g in the voltage range of 1.6-3.0 V, namely the specific discharge capacity of S cathodes with cycling number.

FIG. 8B shows the electrochemical performance of the S cathode electrodes with different amounts of TiO₂ nanoparticles at a current density of 600 mA/g in the voltage range of 1.6-3.0 V, namely the Coulombic efficiency of the different S cathodes with cycling number.

FIG. 9 illustrates applying ALD to deposit nanoclusters of <2 nm on large-surface-area substrates, (b) the resultant nanocluster-support composites are mixed with (c) PVDF, (d) carbon black, and (e) S particles to fabricate (f and g) S cathodes. (f) shows the top view and (g) shows the cross-sectional view of the resultant S cathodes.

FIG. 10 illustrates the composition of ALD-TiO₂/N-GNS composites varying with ALD cycles.

FIGS. 11A, 11B and 11C show the effects of ALD-TiO₂ deposited on N-GNS on S cathodes.

FIG. 12A shows the effects of MLD-LiGL deposited on Li anodes on Li-S cells, namely the sustainable capacity with cycles and (b) Coulombic efficiency with cycles.

FIG. 12B shows the effects of MLD-LiGL deposited on Li anodes on Li-S cells, namely the coulombic efficiency with cycles.

FIG. 13 shows the effects of MLD-LiGL deposited on Li anodes on rate capability of Li-S cells.

FIGS. 14A and 14B show the combined effects of MLD-LiGL and ALD-TiO_{2 on} the performance of Li-S cells.

### DETAILED DESCRIPTION OF THE INVENTION

Detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a representative basis for teaching one skilled in the art to variously employ the present invention in virtually any appropriately detailed method, structure, or system. Further, the terms and phrases used herein are not intended to be limiting, but rather to provide an understandable description of the invention.

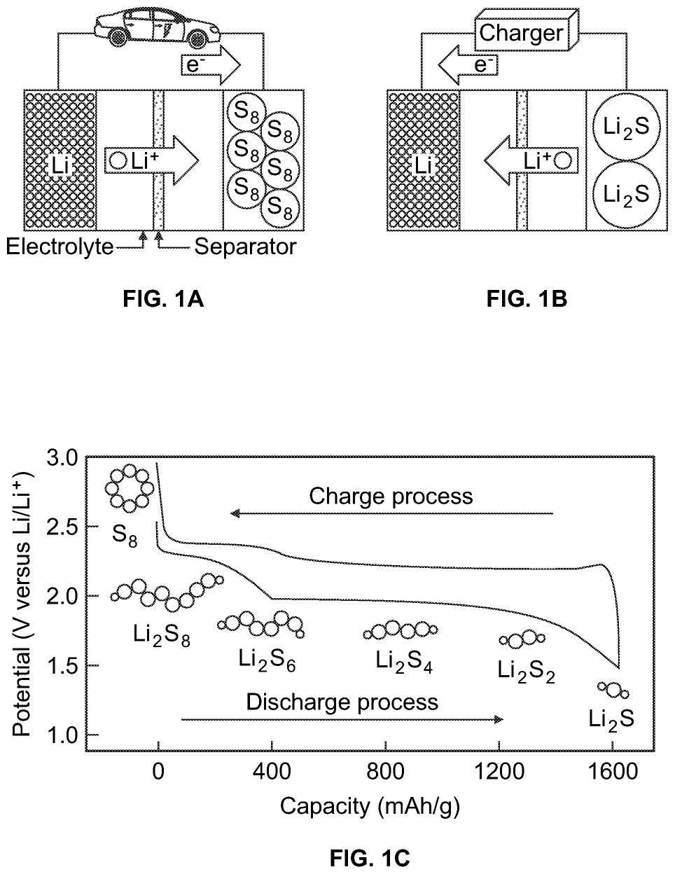

A typical Li-S cell consists of a Li metal anode, an S or a Li₂S cathode, a liquid electrolyte consisting of an organic solvent and a dissolved lithium salt, and an electronically insulating separator, as illustrated in FIG. 1a,b. During a discharge process (FIG. 1a,c), the S cathode (typically in the form of S₈) undergoes several reduction processes to the final discharge (reduction) product of Li₂S, in which there are several intermediates produced, i.e., lithium polysulfides (LPSs, Li₂Sₙ with n=3-8) (FIG. 1c). These reactions are reversible in a subsequent charge (oxidation) process (FIG. 1b,c). A typical discharge profile of Li-S battery in an ether-based electrolyte has two discharge voltage plateaus at 2.2-2.3 V and 1.9-2.1 V, respectively (FIG. 1c).

### S Cathodes

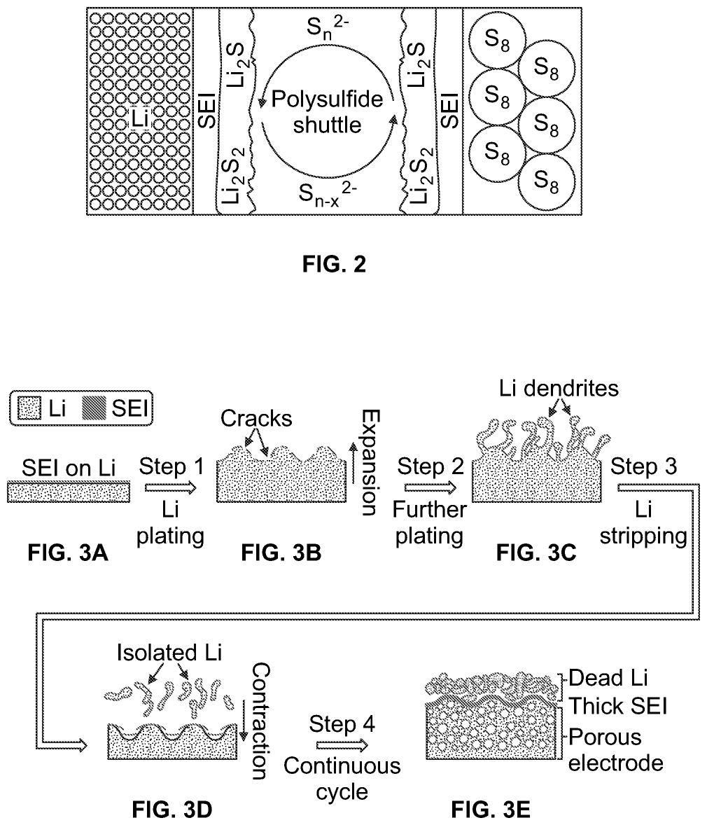

There have three main issues on the S cathode side:
(1). Low conductivity of sulfur(S) and lithium sulfide (Li₂S). The electrically and ionically insulating nature of S and Li₂S makes it difficult to fully utilize the active material, and also leads to the low power of Li-S batteries at 25° C.
(2). Dissolution of intermediate lithium polysulfides (Li₂Sₙ, 3≤n≤8) into the ether electrolyte. During the discharge/charge process, long-chain lithium polysulfides can dissolve into the electrolytes and then diffuse to the Li anode (FIG. 2). The diffused polysulfides are readily reduced chemically by lithium to form low-order polysulfides. The resultant lower-order polysulfides then can diffuse back to the sulfur cathode to be re-oxidized. This parasitic polysulfide shuttle effect is essentially an internal short, leading to continuous loss of the active material S, self-discharging, a rapid capacity decay, and low Coulombic efficiency during cycling.
(3). Large volumetric changes of the sulfur cathode. S undergoes a large volumetric expansion of ˜80% upon a full lithiation to Li₂S, which can cause S pulverization and structural damage at the electrode level, leading to undesirable contact to current collector and thereby unreliable cyclability.

To improve the conductivity of S cathodes, a variety of conductive additives have been attempted and can be categorized into two classes: carbon materials (e.g., carbon black, carbon nanotubes, carbon nanofibers, hollow carbon spheres, and graphene) and conductive polymers (e.g., polypyrrole, polyaniline, and poly(3,4-(ethylenedioxy)thiophene). These conductive materials improved the conductivity of S cathodes via two routes: (1) forming a conductive network and (2) enhancing connection between the conductive framework and the insulating S active material. They also can absorb polysulfides from shuttling and accommodate volume changes of S active materials to some extent. Some other studies have addressed the effects of various absorbing agents on polysulfides. In this regard, metal oxides such as TiO₂, Al₂O₃, SiO₂, and NiO are the most frequently investigated. All these added materials are inactive electrochemically and thus have no contributions to the capacities of S cathodes but reduce their capacities at the electrode level, commonly called passive materials. To harvest a high capacity of S cathodes, it is apparent that the added amount of these passive materials should be minimized while enables to address existing issues. In general, S cathodes reported in literature had a S content of <60 wt % and a S loading of <1 mg/cm². In return, the cathode capacity has been adversely reduced. To satisfy transportation electrification, it is believed that S cathodes should have a S content of ≥70 wt % and S loading of ≥2 mg/cm.² Thus, it is urgent to develop new strategies to reduce the addition of passive materials while improve their effects as conductive or absorbing agents.

### Lithium Anodes

The issues of Li anodes lie in two main aspects: (1) non-uniform and unstable solid electrolyte interphase (SEI) and (2) Li dendritic growth. Li metal is highly reactive to organic liquid electrolytes (OLEs), leading to the formation of an SEI layer on its surface (FIG. 3a). The SEI layer is ionically conducting but electrically insulating. In addition, the SEI layer is also mechanically fragile and mosaic in composition. During Li plating, the huge volume expansion of Li anodes can rupture the fragile and mosaic SEI layer (FIG. 3b), promoting a preferential Li deposition through the cracks with the production of Li dendrite growth (FIG. 3c). During Li stripping, volume contraction further fractures the SEI layer, while stripping from kinks in a dendrite or from its roots can break the electrical contact and produce “dead” Li that is electrically isolated from the substrate (FIG. 3d). After continuous Li plating/stripping cycles, the repeated process can produce a porous Li anode consisting of a thick accumulated SEI layer and excessive dead Li, leading to blocked ion transport and capacity fading (FIG. 3e). In addition, Li dendrites can potentially penetrate the separator and lead to internal short circuits, posing serious safety hazards. Apparently, Li anodes are mainly harassed by the unstable SEI layer and the Li dendrite growth. To address these issues associated with Li anodes, four technical strategies have been developed: (i) electrolyte additives, (ii) solid state electrolytes, (iii) surface modifications, and (iv) 3D Li-hosting frameworks. However, progress to date has been insufficient for commercialization and new efforts are urgently needed.

### Designs of Sulfur Electrodes

### Effects of Conductive Additives

Two different conductive additives may be used with the embodiments of the present invention, TIMICAL SUPER C65 carbon black (CB, MTI, USA) and nitrogen-doped graphene nanosheets (N-GNS, ACS Material, USA). The N-GNS powders are crystalline, containing ˜4 at. % nitrogen and ˜7 at. % oxygen. Typically, they are 1-5 atomic layer thick (<2 nm) and 0.5-5 μm in size. They are morphologically wrinkled and have a surface area of 600-700 m²/g. They have been used in our previous studies. In contrast, CB is polycrystalline carbon with structural defects and primarily less than 50 nm in particle size. The CB has a relatively small surface area of 62 m²/g.

To investigate the effects of the CB and N-GNS, three types of S cathodes were fabricated: (1) using CB, (2) using N-GNS, and (3) using mixtures of CB/N-GNS in different mass ratios as the conductive additive, respectively. Correspondingly, the resultant S cathodes were signified as S_{CB}, S_{N-GNS}, and S_{CB/N-GNS}.

To fabricate these S cathodes, S nanoparticles (Sigma Aldrich, USA) were mixed with a conductive additive (CB, N-GNS, or a mixture of CB/N-GNS) and a polyvinylidene fluoride (PVDF, MTI, USA) as the resin binder in a mass ratio of 60:30:10 in the solvent of N-methyl-2-pyrrolidone (NMP, Sigma-Aldrich, USA) via a 2-hour ball milling process. Three different ratios were used for preparing the mixtures of CB/N-GNS, 2:1, 1:1, and 1:2. The mixtures were used in S cathodes with a content of 30 wt. % to replace CB or N-GNS. The received slurries were then cast on Al foils and expanded into laminates using a 200-μm thick doctor blade. The laminates were first dried in air at room temperature. Then, the dried laminates were further evacuated to remove moisture and solvents via an overnight vacuum. Then, the received laminated were punched into 7/16″ circular electrodes to couple with lithium metal anodes in CR2032 coin cells for electrochemical tests. The S electrodes typically have an S loading of 1-2 mg/cm².

### Effects of TiO₂ Nanoparticles

In one embodiment of the present invention, 30-nm TiO₂ nanoparticles were added in S cathodes to evaluate their effects on the performance of the resultant S cathodes. The added TiO₂ nanoparticles were expected to adsorb intermediate lithium polysulfides (Li₂Sₙ, n≥3) and thereby improve the sustainable capacity and Coulombic efficiency (CE) of the resultant S cathodes. The added TiO₂ nanoparticles are 10, 15, and 20 wt. % of the total weight of S nanoparticles, CB conductive additive, and PVDF binder. The mass ratio of S:CB:PVDF was 70:20:10. The resultant S cathodes were named as S_{TO0} (Bare), S_{TO10}, ST_{O15}, and S_{TO20}.

### Designs of Lithium Anodes

Lithium (Li) metal foils were used to couple with S cathodes to constitute Li-S battery cells. In addition to bare Li metal foils, Li anodes coated with a protective layer of a polymeric film, LiGL (GL=glycerol) were also developed using molecular layer deposition (MLD) at 150° C.⁵⁰ The protective layer of LiGL was deposited with different MLD cycles, 200, 250, and 300. The resultant Li anodes were named as LiGL0 (Bare), LiGL200, LiGL250, and LiGL300.

### Materials Characterization

S cathodes were examined using a scanning electron microscopy (SEM, XL30, Philips FEI) equipped with an energy-dispersive X-ray spectroscopy (EDX). Synchrotron-based X-ray diffraction (XRD) was performed at the beamline 13 BM-C at Advanced Photon Source (APS) at Argonne National Laboratory (IL, USA) for verifying the crystallinity of the S powders in different cathodes. The X-ray wavelength was 0.4336 Å.

### Electrochemical Evaluations

S cathodes were assembled into CR2032 coin cells in a glove box filled with Ar gas. The H₂O and O₂ concentration were controlled below 0.01 ppm. Li foils were used as the counter electrodes and Celgard 2325 was used as the separator. The electrolyte was 1 M bis(trifluoromethane)sulfonamide lithium salt (LiTFSI, Sigma Aldrich) in 1,3-dioxolane (DOL) and 1,2-dimethoxyethane (DME) (1:1, v/v) (Sigma Aldrich) and each cell contained 20 μl of the electrolyte. The cells were rested for 20 hours before electrochemical tests. The galvanostatic discharge-charge tests were carried out at room temperature (25° C.) at different current densities ranging from 0.1 to 2 C (1 C=1,600 mA/g) in the potential range of 1.6 to 3.0 V using a BTS4000 battery testing system (Neware, Shenzhen, China).

The evolutions of cell impedance were measured using electrochemical impedance spectroscopy (EIS, SP-200, Bio-Logic). The EIS spectra were recorded in the frequency range between 1 MHz and 0.01 Hz using an AC perturbation voltage amplitude of 5 mV. The obtained EIS data were fitted using an EC-Lab® V11.12 software. The EIS measurements were performed with the cells in their fully charged states after the first, fifth, tenth, thirtieth, or sixtieth discharge-charge cycle.

### Results

### Effects of Conductive Additives on Li-S Cells

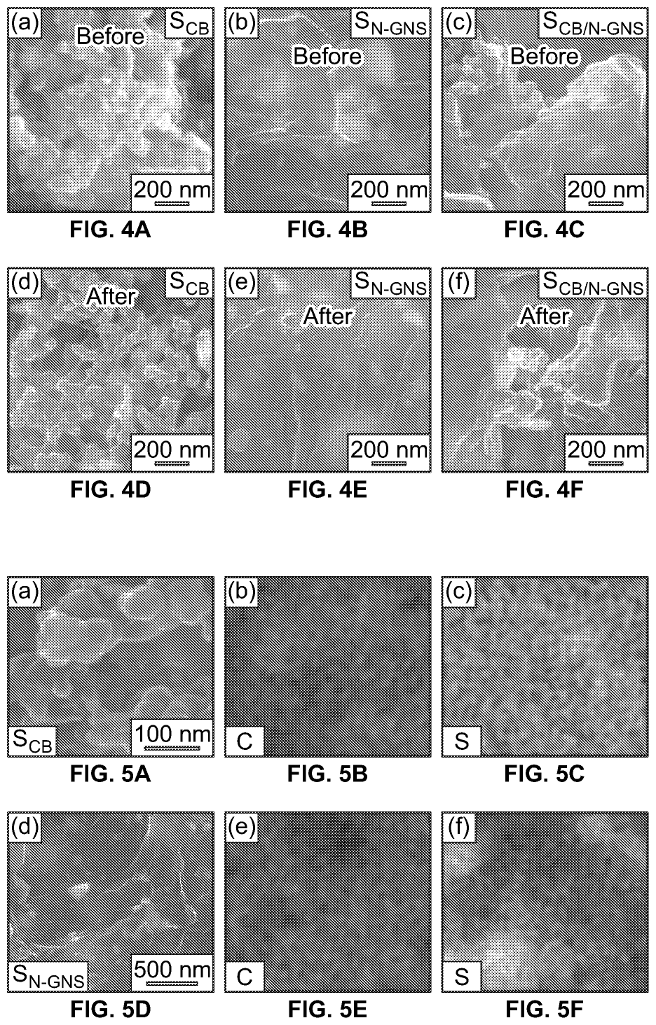

SEM images in FIG. 4 illustrate the changes of S_{CB}, S_{N-GNS}, and S_{CB/N-GNS} electrodes before and after 60 discharge-charge cycles. FIGS. 4a and 4d show the morphological changes of the S_{CB} electrode. The pristine S_{CB} electrode (FIG. 4a) dominantly consists of ˜50-nm nanoparticles. These nanoparticles are S and CB but are not distinguishable. After 60 discharge-charge cycles, the appearance of the S_{CB} electrode evolved from a relatively dense structure into a remarkably porous structure (FIG. 4d). Meanwhile, the nanoparticles are reduced in their sizes. These changes of the S_{CB} electrode seems related to S shuttling, which might have caused some soluble LPSs to shuttle towards and deposit on the Li anode, leading to the reduced sizes of the S nanoparticles and the creation of voids. In contrast, the S_{N-GNS} electrode shows some distinct changes different from the S_{CB} electrode. The pristine S_{N-GNS} electrode (FIG. 4b) shows nanoparticles (200-500 nm) wrapped by the N-GNS. The N-GNS forms a stable interface between the electrolyte and S active material. After 60 discharge-charge cycles, the S_{N-GNS} electrode remains intact, but a large number of tiny nanoparticles (˜10 nm) formed uniformly underneath the N-GNS layer (FIG. 4e). Meanwhile, the original S particles have become smaller in their sizes (<100 nm). In fact, the smaller S nanoparticles were due to the redeposition of S active materials. During the redeposition, the N-doped sites might have exerted remarkable influence. In this regard, previous studies have revealed that the dopant N atoms have much stronger affinity with the polar Li₂S and LPSs than that of the pristine carbon atoms. Thus, N-GNS might have acted as both a physical barrier and a chemical adsorbent of LPSs. Interestingly, using the 1:1 CB/N-GNS mixture as the conductive additive, the original S_{CB/N-GNS} electrode (FIG. 4c) consists of both N-GNS-wrapped and exposed S nanoparticles (˜50 nm), much smaller than those in the S_{N-GNS} electrode. After 60 discharge-charge cycles, the S_{CB/N-GNS} electrode shows tiny, redeposited S nanoparticles wrapped by N-GNS and reduced S nanoparticles exposed (FIG. 4f).

FIG. 5 shows the elemental maps of S_{CB} and S_{N-GNS} electrodes obtained using EDX. FIGS. 5a and 5d are the SEM images of the selected area of the S_{CB} and S_{N-GNS} electrodes before electrochemical cycling, respectively. As shown in FIGS. 5b and 5e, the carbon mapping illustrates the skeletons of the electrodes that were constructed by the CB and N-GNS, respectively. The electrochemically active S is shown in FIGS. 5c and 5f for the S_{CB} and S_{N-GNS}, respectively. Apparently, the carbon distribution is consistent to the S distribution in both the S_{CB} and S_{N-GNS} electrodes.

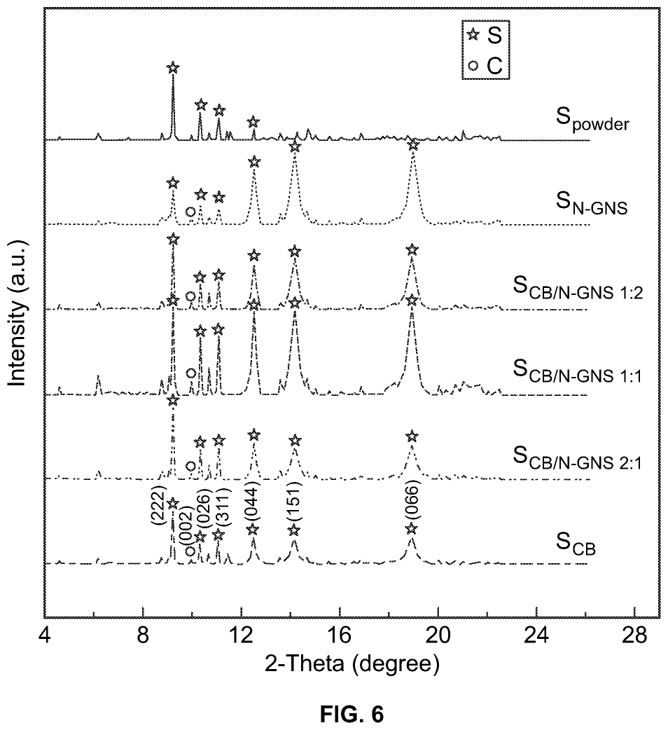

FIG. 6 shows the synchrotron-based XRD patterns of different composite S electrodes fabricated in this study. All these electrodes did not exhibit any observable difference but clearly showed identical XRD characteristic peaks of crystalline S. The CB and N-GNS were not identifiable, due to their nanoscale structures and limited amount in the fabricated S electrodes.

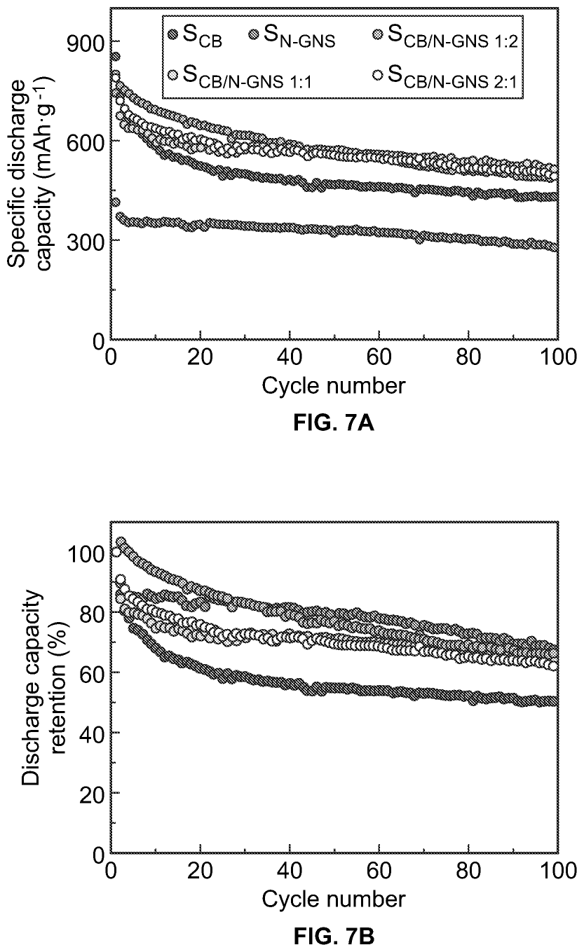

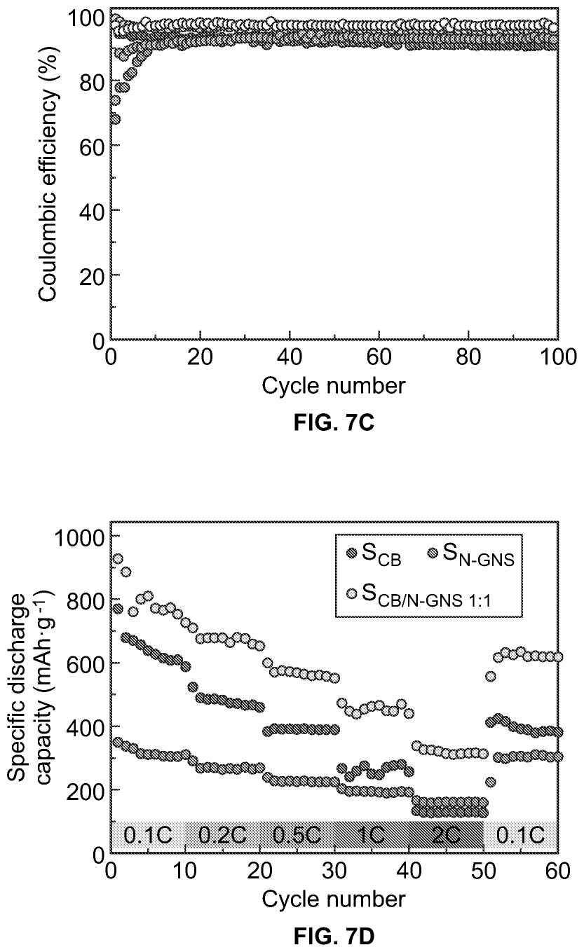

FIG. 7 illustrates the electrochemical performance of the S_{CB}, S_{N-GNS}, and S_{CB/N-GNS} electrodes with different CB/N-GNS ratios (i.e., 1:1, 1:2, and 2:1). FIG. 7a shows the evolution of specific discharge capacity with discharge-charge cycles. Surprisingly, it was found the S_{CB} electrode enabled a discharge capacity of 854.8 mAh·g⁻¹ while the S_{N-GNS} only achieved a discharge capacity of 414.9 mAh·g⁻¹ for the first cycle. The low discharge capacity of the S_{N-GNS} electrode could be due to the retardation of the N-GNS on Li-ion transportation. In fact, Li⁺ ions tend to diffuse through the N-GNS edges rather than its hexagonal carbon ring, since the potential barrier (0.32 eV) for Li-ions to diffuse over the ideal graphene surface is much smaller than the one for Li-ions to penetrate the hexagonal carbon ring (10.68 eV). Although there are vacancies on the N-GNS, the potential barrier for Li-ions to penetrate is as high as 10.25 eV, due to the formation of localized bond between Li ions and the marginal carbon of the vacancy. In discharge capacity retention, very differently, the S_{N-GNS} could sustain 66.1% while the S_{CB} could only remain 50.2% after 100 discharge-charge cycles. Apparently, the CB facilitated the transportation of Li-ions and electrons while the N-GNS enabled exceptional electron transportation but retarded Li-ion transportation. However, the higher capacity retention of the S_{N-GNS} implied that the N-GNS could inhibit shuttling of LPSs as a physical barrier and stabilize the interface of the S_{N-GNS} as an artificial SEI. Indeed, N-GNS has fewer surface defects and enables a stable interface for the S_{N-GNS}.

Motivated by the effects of both the CB and N-GNS, the effects of the mixtures of CB/N-GNS in different mixing ratios, 1:2, 1:1, and 2:1 were investigated. Compared to the S_{CB} and S_{N-GNS} electrodes, all the three S_{CB/N-GNS} electrodes exhibited improvement in their sustainable discharge capacities after 100 discharge-charge cycles (FIG. 7a). Compared to the S_{CB} electrode, furthermore, the S_{CB/N-GNS} electrodes also show remarkable improvements in their discharge capacity retention (FIG. 7b), comparable to the S_{N-GNS} electrode after 100 discharge-charge cycles. In particular, the S_{CB/N-GNS1:1} and S_{CB/N-GNS2:1} have the highest Coulombic efficiency (CE) of ˜98% (FIG. 7c). The CE is calculated through dividing a discharge capacity by a preceding charge capacity. As clearly shown, all the composite electrodes could achieve a steady CE after 20 discharge-charge cycles (FIG. 7c). The S_{CB/N-GNS} electrodes exhibit the highest CEs (˜93.7% to ˜98%), compared to ˜90% for the SCB and ˜93% for the S_{N-GNS}. Additionally, it is interesting to note that the evolution of the CEs of the S_{CB} and S_{N-GNS} is very different in their first 10 discharge-charge cycles. The S_{CB} electrode reaches its highest CE at the first cycle but gradually decreases to a steady value, while the S_{GNS} has its lowest CE at the first cycle and gradually increase to a steady value. This discrepancy should be caused by the distinctive activation process of the S active material in the S_{CB} and S_{N-N-GNS} electrodes. From FIG. 7a-c, it is found the S_{CB/N-GNS} electrodes are able to maintain a long-term high specific capacity after 100 discharge-charge cycles. Among all these S electrodes, the SC_{B/N-GNS1:1} enables the highest specific discharge capacity of 516.7 mAh·g⁻¹ and a good capacity retention of 64.6%. Thus, we have regarded the S_{CB/N-GNS1:1} as the promising candidate for further investigation on rate capability of S cathodes, as shown in FIG. 7d. Ranging from 0.1, 0.2, 0.5, 1, and 2 C (1 C=1675 mA·g⁻¹), the S_{CB/N-GNS1:1} enables the highest specific discharge capacity at all the current rates and recovers to 67.8% of its initial discharge capacity after the first 50 cycles at different rates. Consistent with FIG. 4a, the S_{CB} shows a decent capacity at low rates but drops evidently at high rates (e.g., 1 and 2 C). After the first 50 cycles at different rates, the S_{CB} electrode recovered to 55.1% of its initial discharge capacity. In contrast, the S_{N-GNS} has achieved the highest capacity recovery of 87.8%, although its specific discharge capacity is the lowest in all the cases, except for at 2 C. All these results together reveal that the CB and N-GNS have different distinct effects on the electrochemical performance of the resultant S cathodes. It seems that the CB facilitates the transportation of both electrons and Li-ions while the N-GNS retards the transportation of Li-ions. On the other hand, however, the N-GNS is beneficial to inhibit LPSs from shuttling while the CB cannot effectively suppress shuttling of LPSs.

Interestingly, we further verified that the mixtures of the CB and N-GNS enable much better electrochemical performance, compared to S cathodes using pure CB or N-GNS as the conductive additives.

### Effects of TiO₂ Nanoparticles on Li-S Cells

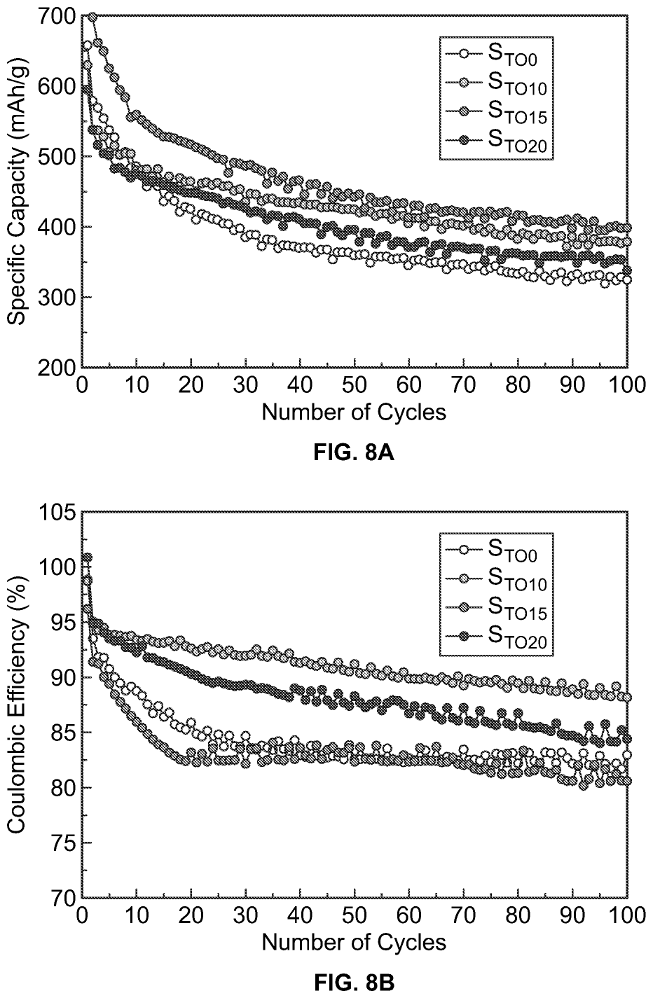

The adsorptive ability of TiO₂ to LPSs was investigated through adding some extra amounts of 30-nm nanoparticles into the mixture of S, CB, and PVDF (the mixture has a ratio of 70:20:10). The extra amounts of TiO₂ nanoparticles are 10, 15, and 20 wt. % of the S/CB/PVDF mixture. The resultant S cathodes, as introduced above, are named as S_{TO0} (Bare), S_{TO10}, S_{TO15}, and S_{TO20} accordingly. In these S cathodes, the percentages of TiO₂ are 0 wt. % for S_{TO0}, 9.1 wt. % for S_{TO10}, 13 wt. % for S_{TO15}, and 16.67 wt. % for S_{TO20}. Among these S cathodes, S_{TO15} enabled the highest sustainable discharge capacity (FIG. 8a) while S_{TO10} enabled the highest Coulombic efficiency (FIG. 8b). The capacities of these S cathodes were calculated using the S amounts. It may be concluded from these results that a considerable amount of 30-nm TiO₂ nanoparticles is needed to improve the performance of S cathodes.

### Effects of ALD-TiO₂ on Li-S Cells

To significantly reduce the addition of TiO₂ in S cathodes, ALD was used to seed nanoclusters (<2 nm) on large-surface-area supports (e.g., N-GNS). Large-surface-area supports can be graphene, carbon nanotubes, metal-organic frameworks (MOFs), or any materials with high surface area (e.g., ≥50 m²/g, the higher the better). ALD is a unique thin film technique enabling deposition of extremely uniform planar two-dimensional (2D) films over flat substrates (e.g., Si wafers) or deposition of unrivaled conformal complex films over complicated substrates (e.g., graphene nanosheets). ALD typically experiences an island growth phase prior to formation of a continuous thin film. The formed island can range from zero to several nanometers, depending on ALD precursors, temperature, and substrate, During this island growth phase, the islands formed are nanoclusters typically less than 2 nm.

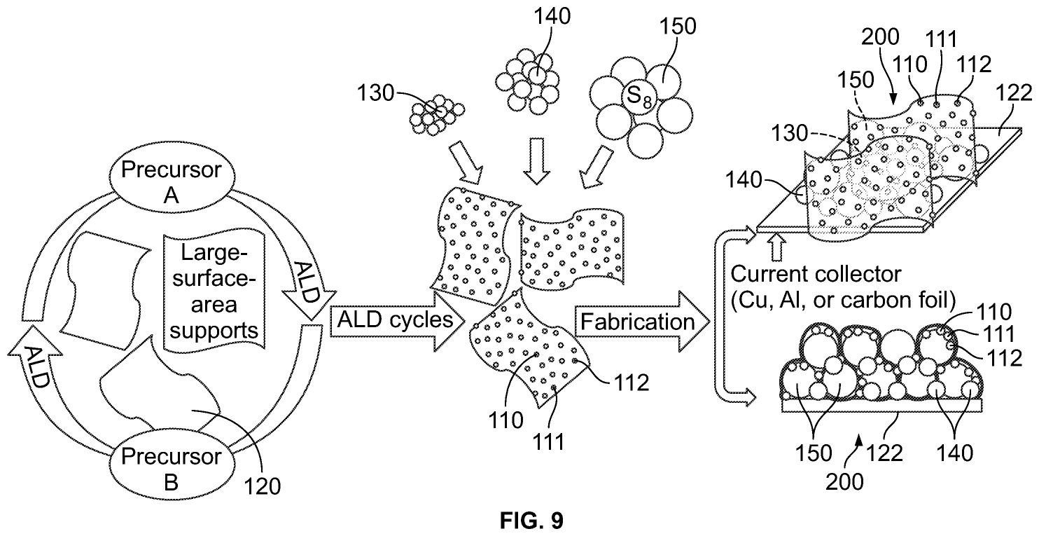

In another embodiment, as shown in FIG. 9, the present invention utilizes this island growth phase to grow a plurality of nanoclusters, such as nanoclusters 110-112 of <2 nm on high-surface-area supports 120, which may be N-GNS, on current collector 122 which may be made of Cu, Al, carbon foil or other materials known to those of skill in the art. This process features ALD's capability in fine-tuning the sizes of nanoclusters 110-112 from zero to 2 nm and the density of nanoclusters. The nanoclusters can be any materials having strong chemical adsorption capability to LPSs (Li₂Sₙ, n≥3), such as elements (e.g., Cu), oxides (e.g., Al₂O₃ and TiO₂), sulfides, nitrides, and so on.

As further shown in FIG. 9, in addition to using ALD to deposit nanoclusters 110-112 of <2 nm on large-surface-area substrates 120 the resultant nanocluster-support composites are mixed with PVDF 130, carbon black (CB) 140, and S particles 150 to fabricate S cathodes 200. In another preferred embodiment, ALD-TiO₂/N-GNS composites may be mixed with CB, PVDF, and S nanoparticles to form S cathodes.

To improve the efficiency of the absorptivity of TiO₂, sub-nano to nanoscale TiO₂ particles were deposited on N-GNS using atomic layer deposition (ALD). The ALD process was performed using titanium tetraisopropoxide (TTIP) and water as precursors at 150° C. The ALD cycles were 5, 10, 20, and 40, i.e., ALD-5, ALD-10, ALD-20, and ALD-40. The resultant TiO₂/N-GNS composites were mixed with S nanoparticles, CB, and PVDF to prepare S cathodes. The resultant S cathodes contained S, CB, N-NGS, and PVDF in the ratio of 70:10:10:10. The percentages of the ALD-TiO₂, compared to the total weight of S, CB, N-GNS, and PVDF, were 1.56 (ALD-5), 3.41 (ALD-10), 5 (ALD-20), and 14.5 wt. % (ALD-40). The resultant S cathodes were named as S_{ALD-0} (Bare), S_{ALD-5}, S_{ALD-10}, S_{ALD-20}, and S_{ALD-40}.

The sizes of nanoclusters can be tuned through adjusting ALD cycles, i.e., the higher the ALD cycles and the larger the nanocluster size. The distribution density of nanoclusters can be tuned through adopting different ALD precursors, ALD temperatures, supports (or substrates), and modifying the surface properties of high-surface-area supports with suitable treatments. Thus, this ALD approach is very flexible to deposit small inorganic nanoclusters with controlled size and density on high-surface-area supports. The resultant nanocluster-support composites are strong chemical adsorbents to LPSs (Li₂Sₙ, n≥3).

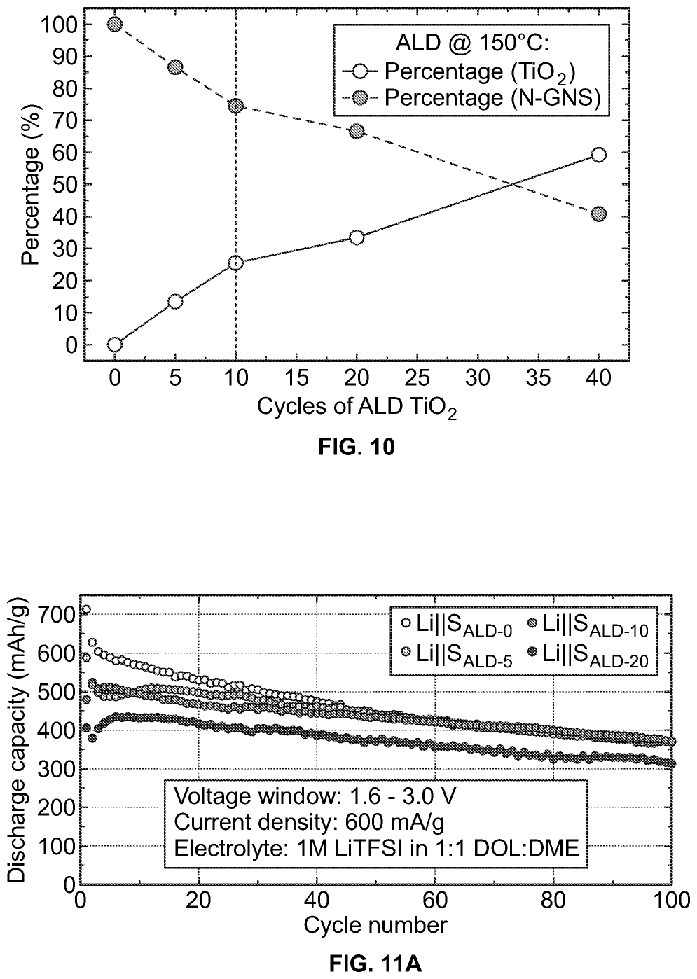

Using TTIP and water as precursors, TiO₂ was deposited on N-GNS with 5, 10, 20, and 40 cycles at 150° C. The ALD-TiO₂ growth per cycle (GPC) is ˜0.275 Å/cycle. Thus, the resultant TiO₂ was supposed to be ˜1.4, 2.75, 5.5, and 11 Å in size after 5, 10, 20, and 40 ALD cycles, respectively. Depositing TiO₂on N-GNS, we found that the resultant TiO₂/N-GNS composites vary in their contents (FIG. 10).

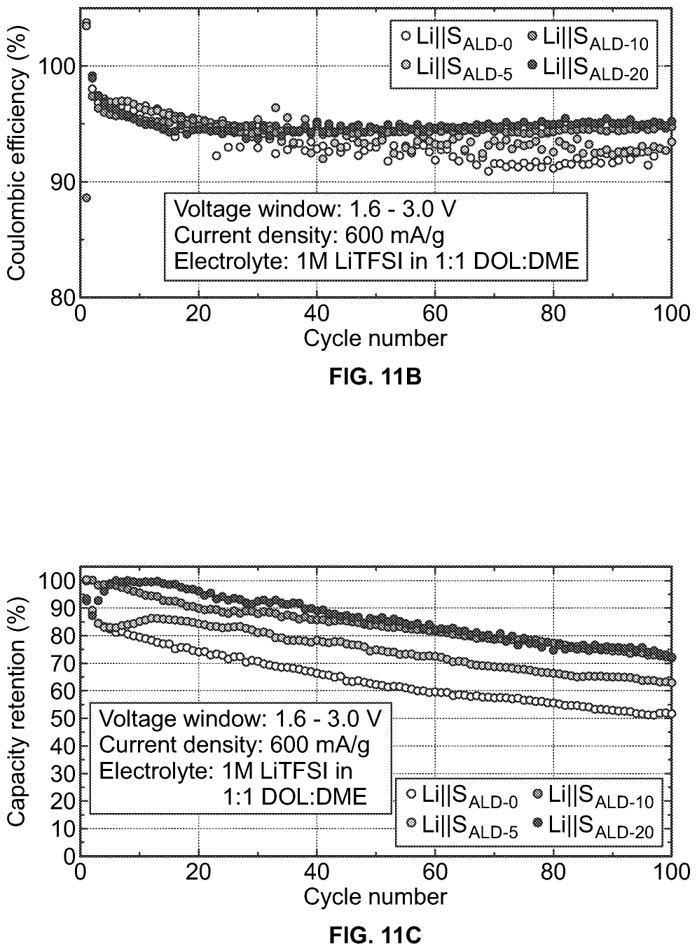

Using ALD-TiO₂/N-GNS composites to mix with CB, PVDF, and S nanoparticles, S cathodes were fabricated, in which the content ratio of S:CB:N-NGS:PVDF is 70:10:10:10. The resultant S cathodes were identified using ALD cycles of TiO₂, i.e., S_{ALD-0} (Bare), S_{ALD-5}, S_{ALD-10}, and S_{ALD-20}. In these S cathodes, the percentages of ALD-TiO₂ are 0 wt. % for S_{ALD-0}, 1.5 wt. % for S_{ALD-5}, 3.3 wt. % for S_{ALD-10}, 4.8 wt. % for S_{ALD-20}, and 12.7 wt. % for S_{ALD-40}. Coupling with Li metal foils, these S cathodes clearly demonstrated that ALD-TiO₂ deposited on N-GNS is beneficial to improve the performance of S cathodes, in terms of sustainable capacity (FIG. 11a), Coulombic efficiency (FIG. 11b), and capacity retention (FIG. 11c). The ALD-TiO₂ strategy greatly reduces the addition of TiO₂ additive but dramatically improves the performance of S cathodes. Compared to the bare S cathode (S_{ALD-0}), the Coulombic efficiency and capacity retention of ALD-modified S cathodes (S_{ALD-5}, S_{ALD-10}, and S_{ALD-20}) have been improved up to ˜2% and 20%, respectively. Among these ALD-modified S cathodes, S_{ALD-10} is the best; that is, there is a desirable ALD coating cycle to maximize the adsorptive effects to LPSs.

### Effects of MLD-LiGL on Li-S Cells

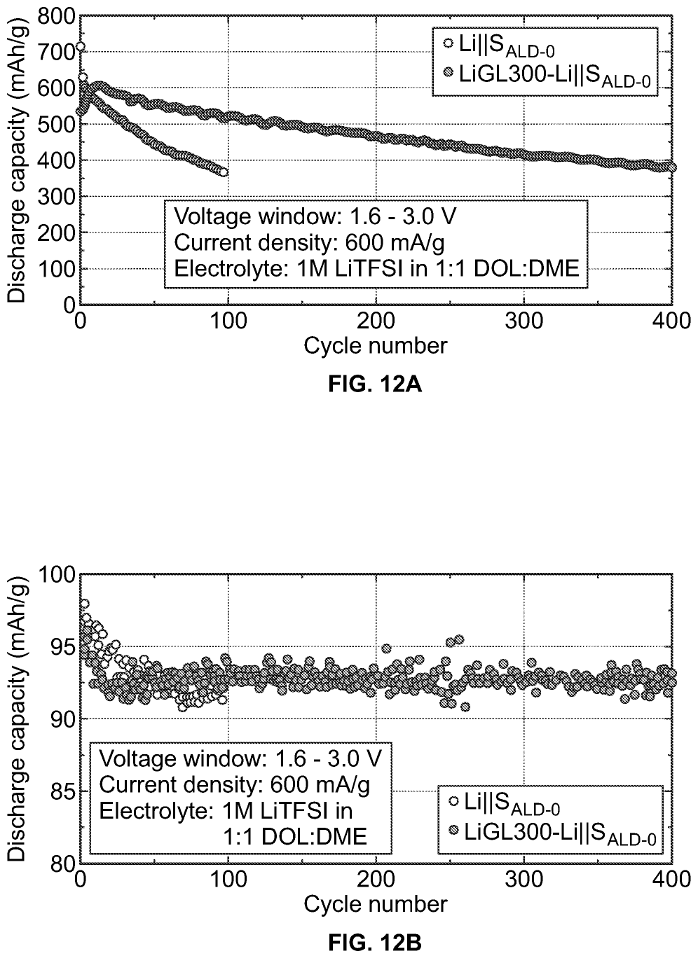

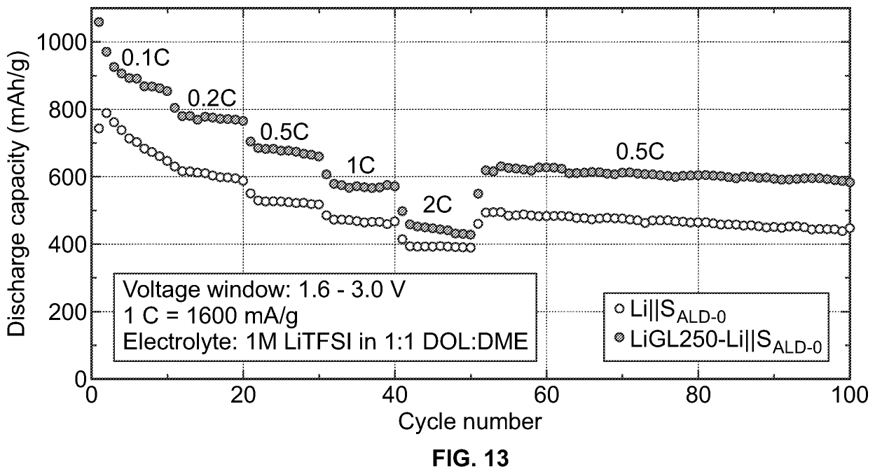

The effects of MLD-LiGL coatings deposited on Li anodes on Li-S cells (FIG. 12) were also investigated. It is easy to conclude that the 300-cycle MLD-LiGL coating (LiGL300) deposited on Li anodes dramatically improved the sustainable capacity of the S_{ALD-0} cathode (FIG. 12a), accounting for an improvement of 200 mAh/g after 100 discharge-charge cycles. The LiGL300-Li anode helped improve the cyclability of Li-S cells. In addition, the LiGL300-Li anode increased the Coulombic efficiency of the Li-S cell (FIG. 12b). Furthermore, the MLD-LiGL coating on Li anodes increases the rate capability of Li-S cells (FIG. 13). Under different current rates (ranging from 0.1 to 0.2, 0.5, 1, and 2 C), the LiGL250-Li∥S_{ALD-0} cell enabled much higher capacities.

### The Combined Effects of MLD-LiGL and ALD-TiO₂ on Li-S Cells

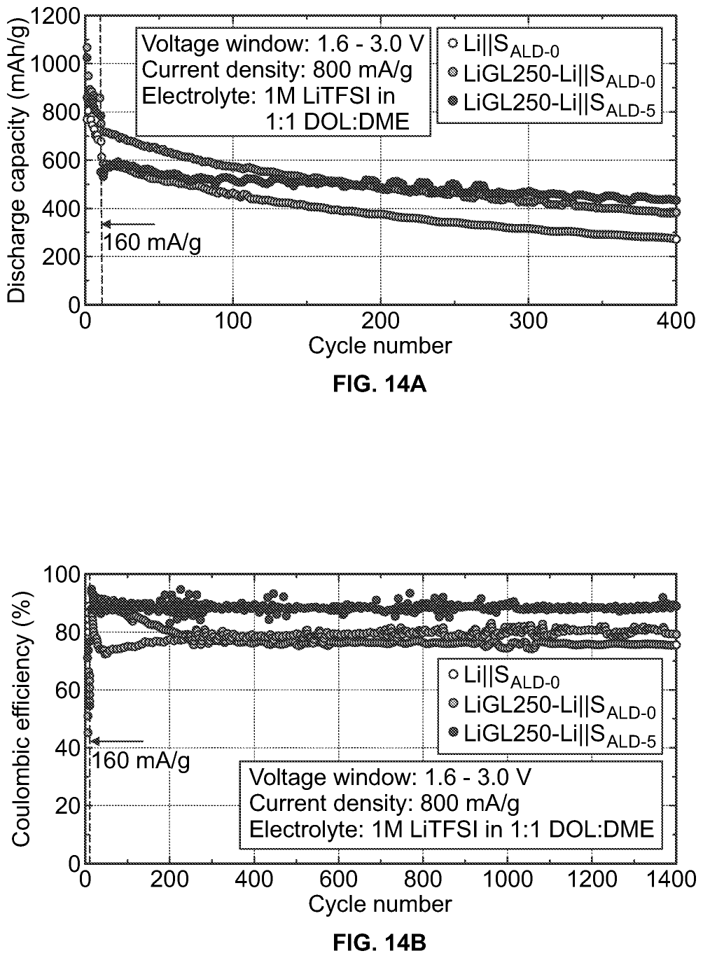

In one embodiment, the present invention investigated the combined effects of MLD-LiGL (GL=glycerol) and ALD-TiO₂ on the performance of Li-S cells (FIG. 14). The LiGL250-Li∥S_{ALD-0} cell performed much better than Li∥S_{ALD-0}, in terms of sustainable capacity (FIG. 14a) and Coulombic efficiency (FIG. 14b). The LiGL250-Li∥S_{ALD-5} cell performed even better than the LiGL250-Li∥S_{ALD-0} cell, in terms of sustainable capacity (FIG. 14a) and Coulombic efficiency (FIG. 14b). The combined ALD and MLD coatings enabled a sustainable capacity of ˜430 mAh/g and a Coulombic efficiency of ˜88% of the LiGL250-Li∥S_{ALD-5} cell versus a capacity of ˜270 mAh/g and a Coulombic efficiency of ˜77% of the Li∥S_{ALD-0} cell after 400 discharge-charge cycles. The MLD-LiGL and ALD-TiO₂ coating are very effective in improving the performance of Li-S cells, in terms of sustainable capacity, Coulombic efficiency, and cyclability.

While the foregoing written description enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above-described embodiments, methods, and examples, but by all embodiments and methods within the scope and spirit of the disclosure.

What is claimed is:

1. A Li-S battery comprising: a cathode and anode, said cathode comprised of a plurality of nanoclusters on a support.

2. The Li-S battery of claim 1 wherein said nanoclusters are made from Cu.

3. The Li-S battery of claim 1 wherein said nanoclusters are made from oxides.

4. The Li-S battery of claim 1 wherein said nanoclusters are made from Al₂O₃.

5. The Li-S battery of claim 1 wherein said nanoclusters are made from TiO₂.

6. The Li-S battery of claim 1 wherein said nanoclusters are made from sulfides.

7. The Li-S battery of claim 1 wherein said nanoclusters are made nitrides.

8. The Li-S battery of claim 1 wherein said nanoclusters are made from one or more of the following: Cu, oxides, Al₂O₃, TiO₂, sulfides, and nitrides.

9. The Li-S battery of claim 1 wherein said support is made from N-GNS.

10. The Li-S battery of claim 1 wherein said nanoclusters are TiO₂ and said support is made from N-GNS.

11. The Li-S battery of claim 1 wherein said nanoclusters are mixed with PVDF, carbon black, and S particles.

12. The Li-S battery of claim 10 wherein said nanoclusters are mixed with PVDF, carbon black, and S particles.

13. The Li-S battery of claim 1 wherein said anode is coated with a protective layer of a polymeric film, LiGL (GL=glycerol).

14. The Li-S battery of claim 10 wherein anode is coated with a protective layer of a polymeric film, LiGL (GL=glycerol).

15. A method of creating an S-cathode for use with a Li-S battery comprising the steps of:
using ALD to create a plurality of nanoclusters on a support.

16. The method of claim 15 wherein said nanoclusters are made from Cu.

17. The method of claim 15 wherein said nanoclusters are made from oxides.

18. The method of claim 15 wherein said nanoclusters are made from Al₂O₃.

19. The method of claim 15 wherein said nanoclusters are made from TiO₂.

20. The method of claim 15 wherein said nanoclusters are made from sulfides.

21. The method of claim 15 wherein said nanoclusters are made nitrides.

22. The method of claim 15 wherein said nanoclusters are made from one or more of the following: Cu, oxides, Al₂O₃, TiO₂, sulfides, and nitrides.

23. The method of claim 15 wherein said support is made from N-GNS.

24. The method of claim 15 wherein said nanoclusters are TiO₂ and said support is made from N-GNS.

25. The method of claim 15 wherein ALD is used to mix PVDF, carbon black, and S particles with said nanoclusters.

26. The method of claim 24 wherein ALD is used to mix PVDF, carbon black, and S particles with said nanoclusters.

27. The Li-S battery of claim 15 wherein said anode is coated with a protective layer of a polymeric film, LiGL (GL=glycerol).

28. The Li-S battery of claim 22 wherein said anode is coated with a protective layer of a polymeric film, LiGL (GL=glycerol).
